(19) United States
(12) Patent Application Publication
(10) Pub. No.: US 2026/0130054 A1
(43) Pub. Date: May 7, 2026

(54) DISPLAY PANEL AND ELECTRONIC APPARATUS COMPRISING THE SAME

(71) Applicant: Samsung Display Co., Ltd., Yongin-si (KR)

(72) Inventors: Jingoo Kang, Yongin-si (KR); Donghoon Kwak, Yongin-si (KR); Dayoung Lee, Yongin-si (KR)

(21) Appl. No.: 19/327,463

(22) Filed: Sep. 12, 2025

(30) Foreign Application Priority Data
Nov. 1, 2024 (KR) 10-2024-0153714

(51) Int. Cl. H10K 59/122; H10K 59/40; H10K 59/80

(52) U.S. Cl. CPC H10K 59/122; H10K 59/40; H10K 59/879

(57) ABSTRACT

A display panel includes a substrate, pixel electrodes disposed on the substrate and each having an isolated shape, a pixel-defining layer covering an edge of each of the pixel electrodes and defining openings through which central portions of the pixel electrodes are exposed, a common electrode integrally formed as a single unitary indivisible body and disposed over the pixel-defining layer and the pixel electrodes, a first inorganic encapsulation layer disposed on the common electrode, a bank layer disposed on the first inorganic encapsulation layer and defining opening portions corresponding to the openings respectively, polymer lenses arranged in the opening portions, where each of the polymer lenses has a refractive index higher than a refractive index of the bank layer, and an upper surface of each of the polymer lenses has a lens shape, and a second inorganic encapsulation layer covering the bank layer and the polymer lenses.

This application claims priority to Korean Patent Application No. 10-2024-0153714, filed on November 1, 2024, and all the benefits accruing therefrom under 35 U.S.C. §119, the content of which in its entirety is herein incorporated by reference.

### BACKGROUND

### 1. Field

One or more embodiments relate to a display panel and an electronic apparatus including the display panel, and more particularly, to a display panel on which a high-quality image may be displayed, and an electronic apparatus including the display panel.

### 2. Description of the Related Art

Display panels are widely used for various electronic apparatuses. In such display panels, pixels have been reduced in size to improve the resolution and display high-quality images, and thus various elements may be arranged in a narrow area.

### SUMMARY

In conventional display panels and electronic apparatuses including the display panels, a high-quality image may not be effectively displayed due to interference between various elements arranged in a narrow area.

One or more embodiments include a display panel on which high-quality images may be displayed, and an electronic apparatus including the display panel.

According to one or more embodiments, a display panel includes a substrate, a plurality of pixel electrodes disposed on the substrate, where each of the plurality of pixel electrodes has an isolated shape, a pixel-defining layer which covers an edge of each of the plurality of pixel electrodes, where openings, through which central portions of the plurality of pixel electrodes are exposed, are defined in the pixel=defining layer, a common electrode disposed above the pixel-defining layer and the plurality of pixel electrodes, and integrally formed as a single unitary indivisible body, a first inorganic encapsulation layer disposed on the common electrode, a bank layer disposed on the first inorganic encapsulation layer, where opening portions corresponding to the openings, respectively, are defined in the bank layer, polymer lenses arranged in the opening portions, where each of the polymer lenses has a refractive index higher than a refractive index of the bank layer, and an upper surface of each of the polymer lenses has a lens shape, and a second inorganic encapsulation layer which covers the bank layer and the polymer lenses.

In an embodiment, an area of each of the opening portions in an upper surface of the bank layer may be greater than an area of a corresponding one of the openings in a lower surface of the pixel-defining layer.

In an embodiment, each of the opening portions may have a greater area at an upper surface of the bank layer than at a lower surface of the bank layer.

In an embodiment, a refractive index of the second inorganic encapsulation layer may be greater than a refractive index of the polymer lenses.

In an embodiment, the display panel may further include a black matrix disposed on the second inorganic encapsulation layer and over the bank layer.

In an embodiment, when viewed from a direction perpendicular to the substrate, the black matrix may be located outside the opening portions and the openings.

In an embodiment, the display panel may further include a touchscreen electrode disposed on the second inorganic encapsulation layer and over the bank layer.

In an embodiment, when viewed from a direction perpendicular to the substrate, the touchscreen electrode may be located outside the opening portions and the openings.

In an embodiment, the plurality of pixel electrodes may include a first-color pixel electrode, a second-color pixel electrode, and a third-color pixel electrode, and a refractive index of one of the polymer lenses corresponding to the first-color pixel electrode may be greater than refractive indices of the polymer lenses corresponding to the second-color pixel electrode and the third-color pixel electrode.

In an embodiment, the lens shape may include a convex lens shape.

In an embodiment, an upper surface of the bank layer may be hydrophobic, and inner surfaces of the bank layer defining the opening portions may be hydrophilic.

According to one or more embodiments, an electronic apparatus includes a display panel, and a lower cover which constitutes an exterior of the electronic apparatus, where an opening, through which a portion of the display panel is exposed, is defined in the lower cover. In such an embodiment, the display panel includes a substrate, a plurality of pixel electrodes disposed on the substrate, where each of the plurality of pixel electrodes has an isolated shape, a pixel-defining layer which covers an edge of each of the plurality of pixel electrodes, where openings, through which central portions of the plurality of pixel electrodes are exposed, are defined in the pixel-defining layer, a common electrode disposed above the pixel-defining layer and the plurality of pixel electrodes, and integrally formed as a single unitary indivisible body, a first inorganic encapsulation layer disposed on the common electrode, a bank layer disposed on the first inorganic encapsulation layer, where opening portions corresponding to the openings, respectively, are defined in the bank layer, polymer lenses arranged in the opening portions, where each of the polymer lenses has a refractive index higher than a refractive index of the bank layer, and an upper surface of each of the polymer lenses has a lens shape, and a second inorganic encapsulation layer which covers the bank layer and the polymer lenses.

In an embodiment, an area of each of the opening portions in an upper surface of the bank layer may be greater than an area of a corresponding one of the openings in a lower surface of the pixel-defining layer.

In an embodiment, each of the opening portions may have a greater area at an upper surface of the bank layer than at a lower surface of the bank layer.

In an embodiment, a refractive index of the second inorganic encapsulation layer may be greater than a refractive index of the polymer lenses.

In an embodiment, the electronic apparatus may further include a black matrix disposed on the second inorganic encapsulation layer and over the bank layer.

In an embodiment, when viewed from a direction perpendicular to the substrate, the black matrix may be located outside the opening portions and the openings.

In an embodiment, the electronic apparatus may further include a touchscreen electrode disposed on the second inorganic encapsulation layer and over the bank layer.

In an embodiment, when viewed from a direction perpendicular to the substrate, the touchscreen electrode may be located outside the opening portions and the openings.

In an embodiment, the plurality of pixel electrodes may include a first-color pixel electrode, a second-color pixel electrode, and a third-color pixel electrode, and a refractive index of one of the polymer lenses corresponding to the first-color pixel electrode may be greater than refractive indices of the polymer lenses corresponding to the second-color pixel electrode and the third-color pixel electrode.

In an embodiment, the lens shape may include a convex lens shape.

In an embodiment, an upper surface of the bank layer may be hydrophobic, and inner surfaces of the bank layer defining the opening portions may be hydrophilic.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating an electronic apparatus according to an embodiment;

FIG. 2 is an exploded perspective view schematically illustrating the electronic apparatus of FIG. 1;

FIG. 3 is a block diagram schematically illustrating the electronic apparatus of FIG. 1;

FIG. 4 is a plan view schematically illustrating a display panel according to an embodiment;

FIG. 5 is a side view schematically illustrating the display panel of FIG. 4;

FIG. 6 is a cross-sectional view schematically illustrating a portion of the display panel of FIG. 4;

FIG. 7 is a cross-sectional view schematically illustrating a display panel according to an embodiment; and

FIG. 8 is a cross-sectional view schematically illustrating a display panel according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

It will be understood that when an element is referred to as being “on” another element, it can be directly on the other element or intervening elements may be present therebetween. In contrast, when an element is referred to as being “directly on” another element, there are no intervening elements present.

In the disclosure, since sizes and thicknesses of components in the drawings are arbitrarily illustrated for convenience of explanation, the following embodiments are not limited thereto. In other words, since sizes and thicknesses of components in the drawings are arbitrarily illustrated for convenience of explanation, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the disclosure, "A and/or B" may include "A," "B," or "A and B." In addition, "at least one of A and B" or "at least one selected from A and B" may include "A," "B," or "A and B." In addition, the expression "at least one of a, b, or c", "at least one selected from a, b, or c" or “at least one selected from a, b, and c” indicates only a, only b, only c, both a and b, both a and c, both b and c, all of a, b, and c, or variations thereof

It will be understood that when a layer, region, or component is referred to as being "connected" to another layer, region, or component, it may be "directly connected" to the other layer, region, or component or may be "indirectly connected" to the other layer, region, or component with another layer, region, or component therebetween. For example, it will be understood that when a layer, region, or component is referred to as being "electrically connected" to another layer, region, or component, it may be "directly electrically connected" to the other layer, region, or component or may be "indirectly electrically connected" to another layer, region, or component with other layer, region, or component therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

One or more embodiments of the disclosure will be described below in more detail with reference to the accompanying drawings. Those components that are the same or are in correspondence are rendered the same reference numeral regardless of the figure number, and any repetitive detailed descriptions thereof may be omitted or simplified.

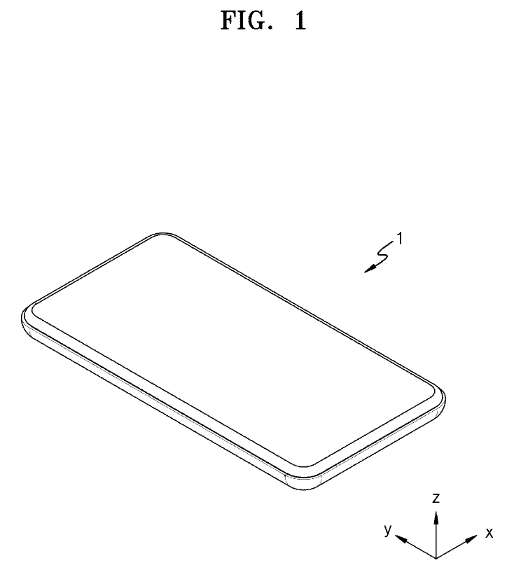

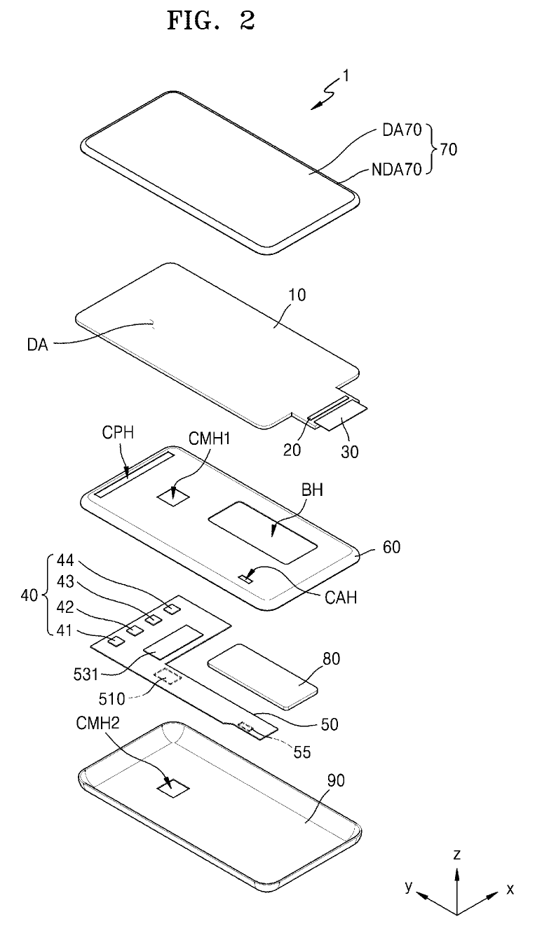

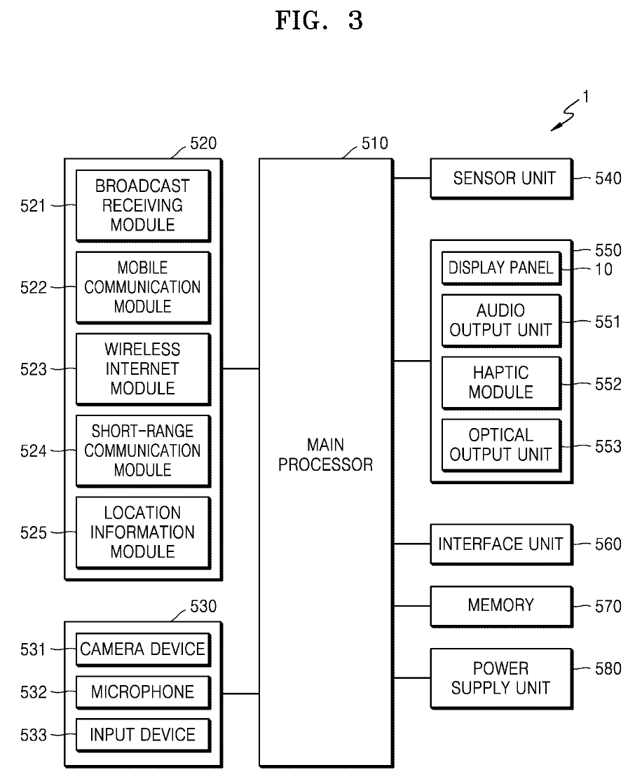

FIG. 1 is a perspective view schematically illustrating an electronic apparatus 1 according to an embodiment. FIG. 2 is an exploded perspective view schematically illustrating the electronic apparatus 1 of FIG. 1. FIG. 3 is a block diagram schematically illustrating the electronic apparatus 1 of FIG. 1.

Referring to FIGS. 1 and 2, the electronic apparatus 1 according to an embodiment is a device for displaying moving images or still images, and may include portable electronic apparatuses, such as mobile phones, smartphones, tablet personal computers (PCs), mobile communication terminals, electronic notebooks, electronic books, portable multimedia players (PMPs), navigations, or ultra mobile PCs (UMPCs), and various products, such as televisions, laptops, monitors, billboards, or Internet of things (IoT) device. In some embodiments, the electronic apparatus 1 may include wearable devices, such as smart watches, watch phones, glasses-type displays, or head-mounted displays (HMDs). In some embodiments, the electronic apparatus 1 may be an instrument panel for a vehicle, a center information display (CID) arranged on a center fascia or dashboard for a vehicle, a room mirror display which replaces a side-view mirror for a vehicle, or a display arranged on a rear surface of a front seat for an entertainment for passengers in a backseat of a vehicle.

For convenience of illustration and description, FIGS. 1 and 2 show an embodiment where the electronic apparatus 1 is a smartphone. In such an embodiment, the electronic apparatus 1 may include a cover window 70, a display panel 10, a data driver 20, a display circuit board 30, a component 40, a bracket 60, a main circuit board 50, a battery 80, and/or a lower cover 90.

In a plan view, "left," "right," "up," and "down" as used herein represent directions when the display panel 10 is viewed from a direction perpendicular to the display panel 10. For example, "left" may represent a -x direction, "right" may represent a +x direction, "up" may represent a +y direction, and "down" may present a -y direction.

In a plan view, an embodiment of the electronic apparatus 1 may have an approximately rectangular shape. In an embodiment, for example, the electronic apparatus 1 may have an approximately rectangular shape which has a short side in an x-axis direction and a long side in a y-axis direction on an xy plane, as shown in FIG. 1. In an embodiment, a corner at which the short side in the x-axis direction and the long side in the y-axis direction meet may form a right angle or may have a round shape having a certain curvature. However, in a plan view, the electronic apparatus 1 may have a polygonal shape other than the rectangular shape, or may have an elliptical shape or an irregular shape.

The cover window 70 may be disposed at an upper portion of the display panel 10 to cover an upper surface of the display panel 10. The cover window 70 may perform a function of protecting the upper surface of the display panel 10.

The cover window 70 may include a transmissive cover portion DA70 corresponding to the display panel 10, and a light-blocking cover portion NDA70 which surrounds the transmissive cover portion DA70. The light-blocking cover portion NDA70 may include an opaque material (e.g., a colored opaque material) which blocks light. The light-blocking cover portion NDA70 may include a pattern to show to a user when an image is not displayed.

The display panel 10 may be disposed under the cover window 70. The display panel 10 may overlap the transmissive cover portion DA70 of the cover window 70. The display panel 10 may include a display area DA. The display area DA is an area in which images are displayed, and may include an area (hereinafter, "component area") which transmits light emitted from the component 40, and the component 40 may be disposed under the display panel 10. The component 40 may include a sensor which uses visible light, infrared light, or sound, and a camera.

The display panel 10 may be a light-emitting display panel which includes a light-emitting diode. The light-emitting diode may be an organic light-emitting diode which includes an organic emission layer, or an inorganic light-emitting diode which includes an inorganic material. In the case of an inorganic light-emitting diode, a PN junction diode including inorganic semiconductor-based materials may be included. When a voltage is applied to a PN junction diode in a forward direction, holes and electrons are injected, and energy generated from recombination of the holes and the electrons may be converted into light energy so that light of a certain color may be emitted. The inorganic light-emitting diode may have a width of several to several hundred micrometers. The inorganic light-emitting diode may also be referred to as a micro light-emitting diode (micro LED).

The display panel 10 may be a rigid display panel which is rigid and does not bend easily, or a flexible display panel which is flexible and may be easily bent, folded, or rolled. In an embodiment, for example, the display panel 10 may be a foldable display panel which may be folded and unfolded, a curved display panel with a curved display surface, a bended display panel with an area other than a display surface curved, a rollable display panel which may be rolled or unrolled, or a stretchable display panel.

The display panel 10 may be a transparent display panel which is implemented transparently and in which an object or background disposed on a lower surface of the display panel 10 is visible through the upper surface of the display panel 10. In some embodiments, the display panel 10 may be a reflective display panel which may reflect an object or background on the upper surface of the display panel 10.

The data driver 20 may be disposed or mounted on the display panel 10 in the form of an integrated circuit (IC). However, one or more embodiments are not limited thereto, and the data driver 20 may be mounted on the display circuit board 30, for example.

The display circuit board 30 may be attached to one side of the display panel 10. The display circuit board 30 may be a flexible printed circuit board (FPCB) which may be bent, a rigid printed circuit board (PCB) which is rigid and is not easily bendable, or a composite printed circuit board including both a rigid PCB and an FPCB. A touch sensor driving unit may be mounted on the display circuit board 30 as described above. The touch sensor driving unit may be formed as (or defined by) an IC. The touch sensor driving unit may be electrically connected to touch electrodes of a touchscreen layer of the display panel 10 through the display circuit board 30.

The touchscreen layer of the display panel 10 may detect a touch input of a user by using at least one of various touch methods, such as a resistive film method or a capacitive method. When the touchscreen layer of the display panel 10 detects a touch input of a user by using the capacitive method, the touch sensor driving unit may apply driving signals to driving electrodes among the touch electrodes and detect, through sensing electrodes among the touch electrodes, voltages charged in mutual capacitances between driving electrodes and sensing electrodes, thereby determining whether the user has touched the cover window 70 etc.

The user's touch may include a contact touch and a proximity touch. The contact touch may indicate that an object, such as a user's finger or an object, such as a pen, is in direct contact with the cover window 70 disposed on the touchscreen layer. The proximity touch may indicate that an object, such as a user's finger or an object, such as a pen, is positioned close to the cover window 70, such as hovering. The touch sensor driving unit may transmit sensor data to a main processor 510 based on the detected voltages, and the main processor 510 may calculate touch coordinates at which a touch input has occurred, by analyzing the sensor data.

A control unit for supplying driving voltages for driving pixels of the display panel 10, a gate driver, and/or the data driver 20 may be disposed on the display circuit board 30.

The bracket 60 for supporting the display panel 10 may be disposed under the display panel 10. The bracket 60 may include plastic, metal, or both plastic and metal. The bracket 60 may define therein a first camera hole CMH1 into which a camera device 531 is inserted, a battery hole BH in which the battery 80 is arranged, a cable hole CAH through which a cable connected to the display circuit board 30 passes, and a component hole CPH corresponding to the components 40. When viewed from a third direction (z-axis direction) or in a plan view, the component hole CPH may overlap the components 40 of the main circuit board 50. In some embodiments, when viewed from the third direction (z-axis direction), the display area DA of the display panel 10 may overlap the components 40 of the main circuit board 50. In another embodiment, the bracket 60 may not be provided with the component hole CPH defined therein, if desired.

The component 40 included in the electronic apparatus 1 may include a first component 41, a second component 42, a third component 43, and a fourth component 44 which overlap the display panel 10 in the third direction (z-axis direction). Each of the first component 41, the second component 42, the third component 43, and the fourth component 44 may include at least one selected from a proximity sensor, an illuminance sensor, an iris sensor, a face recognition sensor, or a camera (or image sensor). The proximity sensor, in which infrared rays are used, may detect an object which is positioned adjacent to an upper surface of the electronic apparatus 1, and the illuminance sensor may detect a brightness of light which is incident on the upper surface of the electronic apparatus 1. In addition, the iris sensor may photograph a person’s iris that may be above the upper surface of the electronic apparatus 1, and the camera may obtain image data for an object disposed on the upper surface of the electronic apparatus 1. However, the component 40 is not limited to the proximity sensor, the illuminance sensor, the iris sensor, the face recognition sensor, and/or the camera, and may include sensors other than those described above.

The main circuit board 50 and the battery 80 may be disposed under the bracket 60. The main circuit board 50 may be a PCB or an FPCB.

The main circuit board 50 may include the main circuit board 50, the camera device 531, a main connector 55, and the components 40. The main processor 510 may be formed as an IC. If desired, the electronic apparatus 1 may include a camera device which is on a lower surface of the main circuit board 50, as well as the camera device 531 which is disposed on an upper surface of the main circuit board 50. Each of the main processor 510 and the main connector 55 may be disposed on either the upper or lower surface of the main circuit board 50. The main circuit board 50 may be electrically connected to the display circuit board 30 through the main connector 55 or the like.

The main processor 510 may control all functions of the electronic apparatus 1. In an embodiment, for example, the main processor 510 may output digital video data to the data driver 20 through the display circuit board 30 such that an image is displayed on the display panel 10. The main processor 510 may receive input of sensing data from the touch sensor driving unit. The main processor 510 may determine a user has touched, according to the sensing data, and execute an operation corresponding to a direct or proximity touch of the user. The main processor 510 may be an application processor, a central processing unit, or a system chip, each of which includes an IC.

The camera device 531 may process image frames, such as still images or moving images, obtained by the image sensor in a camera mode, and output the processed image frames to the main processor 510. The camera device 531 may include at least one selected from a camera sensor (e.g., a charge-coupled device (CCD) or a complementary metal-oxide-semiconductor (CMOS) camera sensor), a photosensor (or image sensor), or a laser sensor.

A cable disposed or passing through the cable hole CAH defined in the bracket 60 may be connected to the main connector 55, and the main circuit board 50 may be electrically connected to the display circuit board 30 via the cable.

Components of the electronic apparatus 1 may also be shown in a block diagram shown in FIG. 3. In addition to the main processor 510, the electronic apparatus 1 may further include a wireless communication unit 520, an input unit 530, a sensor unit 540, an output unit 550, an interface unit 560, a memory 570, and/or a power supply unit 580, as shown in FIG. 3.

The wireless communication unit 520 may include at least one selected from a broadcast receiving module 521, a mobile communication module 522, a wireless Internet module 523, a short-range communication module 524, or a location information module 525.

The broadcast receiving module 521 may receive broadcast signals and/or broadcast-related information from an external broadcast management server via a broadcast channel. The broadcast channel may include satellite channels or terrestrial channels.

The mobile communication module 522 may transmit/receive wireless signals to/from a base station, an external terminal, and an external server, on a mobile communication network established according to technical standards or communication schemes for mobile communication (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), or the like). The wireless signals may include voice call signals, video call signals, or various forms of data according to text/multimedia message transmission and reception.

The wireless Internet module 523 may indicate a module for wireless Internet access. The wireless Internet module 523 may be configured to transmit/receive wireless signals in a communication network according to wireless Internet technologies. For example, the wireless Internet technologies may include Wireless Local Area Network (WLAN), Wireless-Fidelity (Wi-Fi), Wi-Fi Direct, and/or Digital Living Network Alliance (DLNA).

The short-range communication module 524 is for short-range communication and may support short-range communication by using at least one selected from Bluetooth^{TM}, Radio Frequency Identification (RFID), Infrared Data Association (IrDA), Ultra Wideband (UWB), ZigBee, Near Field Communication (NFC), Wi-Fi, Wi-Fi Direct, or Wireless Universal Serial Bus (Wireless USB) technologies. Through the short-range Wireless Area Network (WAN), the short-range communication module 524 may support wireless communication between the electronic apparatus 1 and a wireless communication system, between the electronic apparatus 1 and another electronic apparatus, or between the electronic apparatus 1 and a network in which the other electronic apparatus (or external server) is located. The short-range Wireless Area Networks may be short-range Wireless Personal Area Networks. The other electronic apparatus may be a wearable device which may mutually exchange data (or may be interlocked) with the electronic apparatus 1.

The location information module 525 is a module for obtaining a location of the electronic apparatus 1 and may include a Global Positioning System (GPS) module or a Wi-Fi module.

The input unit 530 may include an image input unit for inputting image signals, such as the camera device 531, an audio input unit for inputting audio signals, such as a microphone 532, or an input device 533 for receiving input of information from a user. The camera device 531 may process image frames, such as still images or moving images, obtained by an image sensor in a video call mode or shooting mode. The processed image frames may be displayed on the display panel 10 or stored in the memory 570. The microphone 532 may process an external audio signal into electrical speech data. The processed speech data may be variously utilized based on functions being performed in the electronic apparatus 1 (or applications being executed).

The main processor 510 may control operations of the electronic apparatus 1 to correspond to information received via the input device 533. The input device 533 may include a mechanical input means, such as a button, a dome switch, a jog wheel, or a jog switch, located on a rear surface or side surface of the electronic apparatus 1, or a touch input means. The touch input means may include a touchscreen layer of the display panel 10.

The sensor unit 540 may include one or more sensors which sense at least one of information in the electronic apparatus 1, surrounding environment information of the electronic apparatus 1, or user information, and generates a sensing signal corresponding to the sensed information. Based on the sensing signal described above, the main processor 510 may control driving or operation of the electronic apparatus 1 or perform data processing, functions, or operations related to applications installed on the electronic apparatus 1. The sensor unit 540 may be the proximity sensor, the illumination sensor, or the face recognition sensor as described above, related to the component 40. In some embodiments, the sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. In addition, the sensor unit 540 may include an environmental sensor or a chemical sensor. In an embodiment, for example, the environmental sensor may be a barometer, a hygrometer, a thermometer, a radiation detection sensor, a heat detection sensor, and/or a gas detection sensor. The chemical sensor may be an electronic nose, a healthcare sensor, and/or a biometric sensor.

The output unit 550 is for generating an output related to vision, hearing, or tactile sensations, and may include at least one of the display panel 10, an audio output unit 551, a haptic module 552, or an optical output unit 553.

The display panel 10 may display (output) information processed in the electronic apparatus 1. In an embodiment, for example, the display panel 10 may display execution screen information of an application running on the electronic apparatus 1, a user interface (UI) according to the execution screen information, or graphical user interface (GUI) information. In such an embodiment, the display panel 10 may function as one of input devices 533 which provide an input interface between the electronic apparatus 1 and the user, while also functioning as one of output units 550 which provide an output interface between the electronic apparatus 1 and the user.

In a call signal reception mode, a call mode, a recording mode, a speech recognition mode, and/or a broadcast reception mode, the audio output unit 551 may output audio data received from the wireless communication unit 520 or stored in the memory 570. The audio output unit 551 may output audio signals related to functions (e.g., a call signal reception sound, a message reception sound, or the like) performed in the electronic apparatus 1. The audio output unit 551 may include a receiver and a speaker. At least one selected from the receiver or the speaker may be an audio generating device which is attached to a lower portion of the display panel 10 and vibrates the display panel 10 and outputs sound. The audio generating device may be a piezoelectric element or piezoelectric actuator which shrinks and expands in response to electric signals, or an exciter which generates magnetic force by using a voice coil and vibrates the display panel 10.

The haptic module 552 may generate various tactile effects which may be felt by a user. The haptic module 552 may provide vibration to the user as a tactile effect. The haptic module 552 may not only deliver a tactile effect through direct contact, but may also be implemented such that a user may feel the tactile effect through muscle sense of his or her fingers or arms.

The optical output unit 553 may output a signal for notifying the occurrence of an event, by using light from a light source. Examples of an event occurring in the electronic apparatus 1 may include receiving a message, receiving a call signal, receiving a missed call, an alarm, a schedule reminder, receiving an e-mail, and/or receiving information through an application. A signal output from the optical output unit 553 may be implemented as the electronic apparatus 1 emits light of one or more colors from the front or rear of the electronic apparatus 1. The signal output may be terminated when the electronic apparatus 1 detects the user's acknowledgement of the event.

The interface unit 560 may serve as a passage for various types of external devices connected to the electronic apparatus 1. The interface unit 560 may include at least one of a wired/wireless headset port, an external charger port, a wired/wireless data port, a memory card port, a port which connects a device having an identification module, an audio input/output (I/O) port, a video I/O port, or an earphones port. When an external device is connected to the interface unit 560, the electronic apparatus 1 may perform appropriate control related to the connected external device.

The memory 570 may store data for supporting various functions of the electronic apparatus 1. The memory 570 may store a plurality of application programs running on the electronic apparatus 1, data for operations of the electronic apparatus 1, and/or instructions. At least one selected from the plurality of applications may be downloaded from an external server through wireless communication. The memory 570 may store applications for operating the main processor 510 or may temporarily store input/output data, such as a phonebook, messages, still images, and/or moving images. In addition, the memory 570 may store haptic data for vibration of various patterns provided to the haptic module 552 and audio data regarding various sounds provided to the audio output unit 551.

The memory 570 may include at least one type of storage medium selected from a flash memory type, a hard disk type, a solid state disk (SSD) type, a silicon disk drive (SDD) type, a multimedia card micro type, a card-type memory (e.g., Secure Digital (SD) or eXtreme Digital (XD) memory), random access memory (RAM), static random access memory (SRAM), read-only memory (ROM), electrically erasable programmable read-only memory (EEPROM), programmable read-only memory (PROM), magnetic memory, a magnetic disk, or an optical disk.

Under the control by the main processor 510, the power supply unit 580 may receive external power and/or internal power and supply the power to each of elements included in the electronic apparatus 1. The power supply unit 580 may include the battery 80. In addition, the power supply unit 580 may include a connection port, and this connection port may be an example of the interface unit 560 to which an external charger which supplies power for charging the battery 80 is electrically connected. In some embodiments, the power supply unit 580 may allow the battery 80 to be charged wirelessly. In an embodiment, as shown in FIG. 2, the battery 80 may be arranged not to overlap the main circuit board 50 in the third direction (z direction). The battery 80 may overlap the battery hole BH defined in the bracket 60.

In an embodiment, as shown in FIG. 2, the lower cover 90 may form the exterior of the electronic apparatus 1 and may define therein an opening which exposes a portion of the display panel 10. The lower cover 90 may be assembled with the display panel 10 such that the display area of the display panel 10 is exposed through the opening of the lower cover 90. The lower cover 90 may be on the opposite side of the cover window 70 with the display panel 10 between the lower cover 90 and the cover window 70. The lower cover 90 may be disposed under the main circuit board 50 and the battery 80. The lower cover 90 may be coupled (e.g., fastened and fixed) to the bracket 60. The lower cover 90 may constitute the exterior of a lower surface of the electronic apparatus 1. The lower cover 90 may include plastic, metal, or both plastic and metal.

A second camera hole CMH2 through which a lower surface of the camera device 531 is exposed may be defined in the lower cover 90. A location of the camera device 531 and locations of the first camera hole CMH1 and the second camera hole CMH2 corresponding to the camera device 531 are not limited to those shown in FIGS. 1 and 2, and may be variously modified.

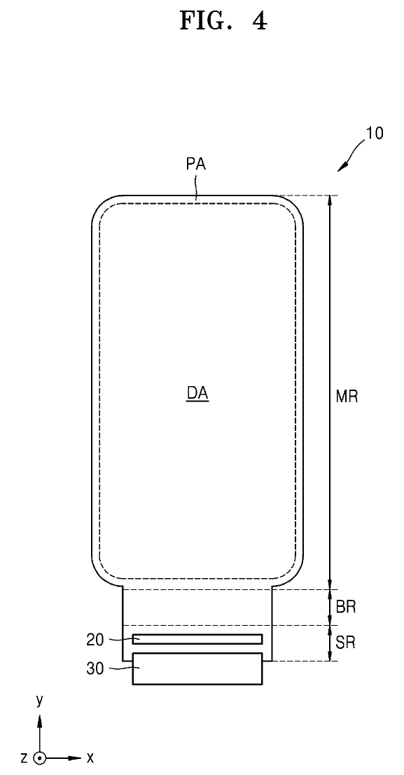

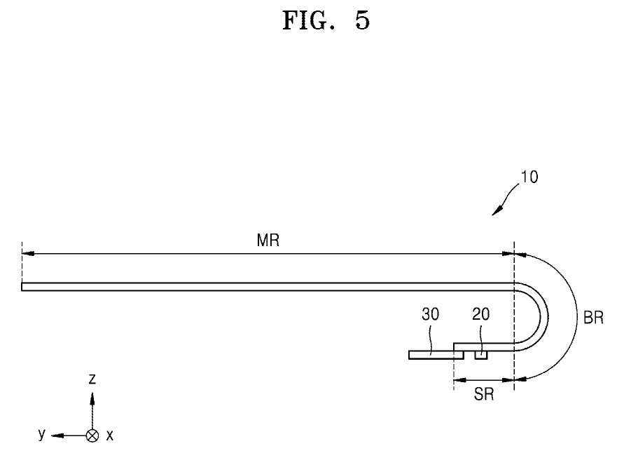

FIG. 4 is a plan view schematically illustrating the display panel 10 according to an embodiment, and FIG. 5 is a side view schematically illustrating the display panel 10 of FIG. 4. An embodiment of the electronic apparatus 1 described above may include the display panel 10 as shown in FIGS. 4 and 5.

The display panel 10 may include the display area DA and a peripheral area PA which is outside the display area DA. The display area DA is a portion for displaying images, and a plurality of pixels may be arranged in the display area DA. The display area DA may have various shapes, such as a circular shape, an elliptical shape, a polygonal shape, or a shape of a particular figure. FIG. 4 shows an embodiment where the display area DA has an approximately rectangular shape with round edges as an example, but not being limited thereto.

The peripheral area PA may be located outside the display area DA. A first-direction (x-axis-direction) width of a portion of the peripheral area PA located at a lower end of the display area DA and extending in the first direction (x-axis direction) may be less than a first-direction (x-axis-direction) width of the display area DA. This structure may allow at least a portion of the peripheral area PA to be easily bent.

A planar shape of the display panel 10 shown in FIG. 4 may be substantially identical to a shape of a substrate 101 included in the display panel 10. in an embodiment where the display panel 10 includes the display area DA and the peripheral area PA which is outside the display area DA, the substrate 101 may be understood as including the display area DA and the peripheral area PA outside the display area DA. For convenience of description, it is described below that the substrate 101 includes the display area DA and the peripheral area PA.

The display panel 10 may include a main area MR, a bending area BR which is outside the main area MR, and a sub-area SR which is spaced apart from the main area MR with the bending area BR between the sub-area SR and the main area MR. The main area MR may be arranged on one side of the bending area BR, and the sub-area SR may be arranged on another side of the bending area BR. The display panel 10 may be bent in the bending area BR, as shown in FIG. 5, and when viewed from the third direction (z-axis direction), at least a portion of the sub-area SR may overlap the main area MR. FIG. 5 shows an embodiment of the display panel 10 in a bent state, but one or more embodiments are not limited thereto. In an embodiment, for example, the display panel 10 may be a foldable display panel, and in such an embodiment, the display panel 10 may be bent within the display panel 10 with respect to a bending axis which crosses the display area DA. In some embodiments, if desired, the display panel 10 may not be bent. The sub-area SR may be a non-display area.

The data driver 20 may be arranged in the sub-area SR of the display panel 10. The data driver 20 may be arranged on the display panel 10 in the form of an IC. In an embodiment, for example, the data driver 20 may be a data driving IC which generates data signals.

The display circuit board 30 may be attached to an end of the sub-area SR of the display panel 10. The display circuit board 30 may be electrically connected to the data driver 20 through a pad of the sub-area SR of the display panel 10.

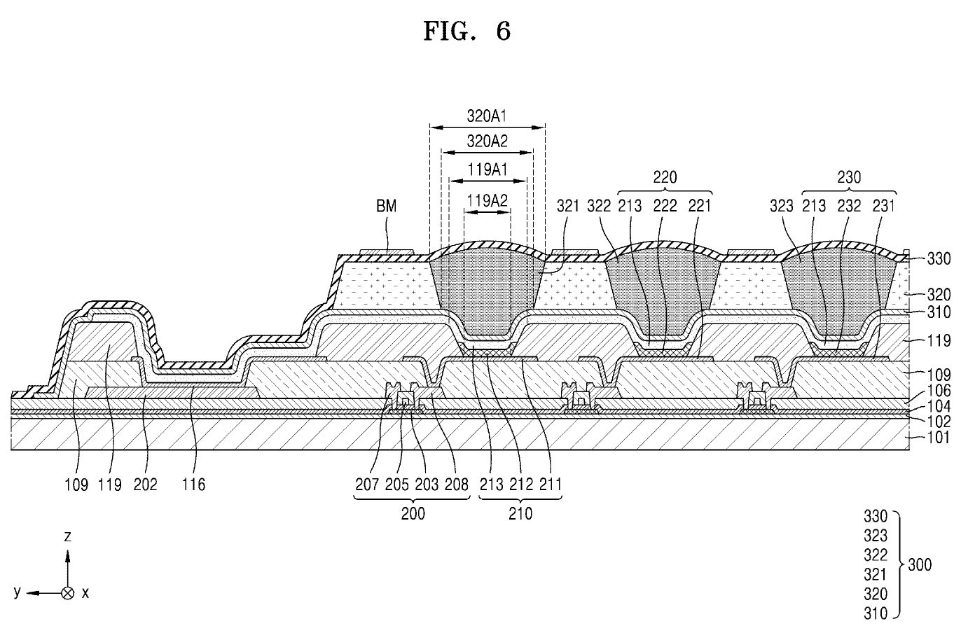

FIG. 6 is a cross-sectional view schematically illustrating a portion of the display panel 10 of FIG. 4. Particularly, FIG. 6 shows a cross-section of the display panel 10 in the display area DA and the peripheral area PA. However, for convenience of illustration and description, some elements are omitted. For example, a scan driver which generates a scan signal to be applied to a scan line within the display area DA may be located in the peripheral area PA, but this scan driver or the like may be omitted in FIG. 6.

In an embodiment, as shown in FIG. 6, the display panel 10 may include the substrate 101. Various elements included in the display panel 10 may be disposed on the substrate 101.

The substrate 101 may include glass, ceramic, metal, or polymer resin. The substrate 101 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 101 may have a multi-layer structure which includes two layers including such polymer resin and an inorganic layer located between the two layers. In some embodiments, the substrate 101 may have a structure in which a layer including such polymer resin and an inorganic layer are alternately stacked. In an embodiment, for example, the inorganic layer may include silicon oxide, silicon nitride, or silicon oxynitride.

Pixels are arranged in the display area DA, and the display area DA may provide images by using light emitted from the pixels. Each of the pixels may include a light-emitting diode, and the light-emitting diode may be electrically connected to a pixel circuit which includes a thin-film transistor or the like. The pixel circuit and the light-emitting diode may be arranged in the display area DA. For convenience of illustration and description, FIG. 6 shows that the pixel circuit includes one thin-film transistor 200, and a light-emitting diode disposed over the pixel circuit is an organic light-emitting diode.

A buffer layer 102 may be disposed over the substrate 101. The buffer layer 102 may planarize an upper surface of the substrate 101 and block impurities, such as oxygen or moisture, permeating from the outside through the substrate 101. The buffer layer 102 as described above may include an inorganic insulating material, such as silicon oxide, silicon nitride, silicon oxynitride, aluminum oxide, aluminum nitride, titanium oxide, titanium nitride, tantalum oxide, hafnium oxide, or zirconium oxide, or an organic insulating material, such as polyimide, polyester, or acryl. The buffer layer 102 may have a single-layered or multi-layered structure. The buffer layer 102 as described above may be located not only in the display area DA but also in the peripheral area PA. The buffer layer 102 may be integrally formed as a single unitary indivisible body throughout the display area DA and the peripheral area PA.

A thin-film transistor 200 and an organic light-emitting diode electrically connected to the thin-film transistor 200 may be located in the display area DA.

The thin-film transistor 200 may include an active layer 203, a gate electrode 205, a source electrode 207, and a drain electrode 208. Hereinafter, an embodiment in which the thin-film transistor 200 is a top gate type where the active layer 203, the gate electrode 205, the source electrode 207, and the drain electrode 208 are sequentially formed will be described as an example. However, one or more embodiments are not limited thereto, and a display device may include the thin-film transistor 200 of various types, such as a bottom gate type.

The active layer 203 may be disposed over the buffer layer 102. The active layer 203 may include a semiconductor material, e.g., amorphous silicon or polycrystalline silicon. However, one or more embodiments are not limited thereto, and the active layer 203 may contain various materials. In an embodiment, for example, the active layer 203 may include an organic semiconductor material or an oxide semiconductor material. In an embodiment where the active layer 203 includes the oxide semiconductor material, the active layer 203 may be an oxide semiconductor including at least one element selected from indium (In), gallium (Ga), tin (Sn), zirconium (Zr), vanadium (V), hafnium (Hf), cadmium (Cd), germanium (Ge), chrome (Cr), titanium (Ti), aluminum (Al), cesium (Cs), cerium (Ce), and zinc (Zn). For example, the oxide semiconductor may include InSnZnO (ITZO) or InGaZnO (IGZO).

A gate insulating film 104 may cover the active layer 203. The gate insulating film 104 may include an inorganic insulating material, such as silicon oxide, silicon nitride, silicon oxynitride, aluminum oxide, aluminum nitride, titanium oxide, titanium nitride, tantalum oxide, hafnium oxide, or zirconium oxide. The gate insulating film 104 may have a single-layered or multi-layered structure. The gate insulating film 104 as described above may enable electrical insulation between the active layer 203 and the gate electrode 205. The gate insulating film 104 may extend to at least a portion of the peripheral area PA as well as the display area DA.

The gate electrode 205 may be disposed over the gate insulating film 104. The gate electrode 205 may be electrically connected to a gate line (not shown) which applies on/off signals to the thin-film transistor 200. In an embodiment, for example, the gate electrode 205, which is a portion of the gate line, may be defined by a portion of the gate line overlapping the active layer 203 when viewed from a direction perpendicular to the substrate 101 (i.e., in a plan view).

The gate electrode 205 may include a metal material. In an embodiment, for example, the gate electrode 205 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu) considering adhesion to adjacent layers, surface flatness of stacked layers, and processability. The gate electrode 205 may have a single-layered or multi-layered structure. In an embodiment, for example, the gate electrode 205 may have a two-layer structure of a Mo layer and an Al layer, or a three-layer structure of a Mo layer, an Al layer, and a Mo layer.

An interlayer insulating film 106 may cover the gate electrode 205. In addition, the source electrode 207 and/or the drain electrode 208 may be disposed over the interlayer insulating film 106. In an embodiment, for example, the interlayer insulating film 106 may electrically insulate the source electrode 207 and the drain electrode 208 from the gate electrode 205. The interlayer insulating film 106 may include an inorganic insulating material, such as silicon oxide, silicon nitride, silicon oxynitride, aluminum oxide, aluminum nitride, titanium oxide, titanium nitride, tantalum oxide, hafnium oxide, or zirconium oxide. The interlayer insulating film 106 may have a single-layered or multi-layered structure. The interlayer insulating film 106 may extend to at least a portion of the peripheral area PA as well as the display area DA.

The source electrode 207 and/or the drain electrode 208 may be disposed over the interlayer insulating film 106. The source electrode 207 and/or the drain electrode 208 may include Al, Pt, Pd, Ag, Mg, Au, Ni, Nd, Ir, Cr, Li, Ca, Mo, Ti, W, or Cu. The source electrode 207 and/or the drain electrode 208 may have a single-layered or multi-layered structure. In an embodiment, for example, the source electrode 207 and/or the drain electrode 208 may have a three-layer structure of a Ti layer, an Al layer, and a Ti layer.

In an embodiment, as shown in FIG. 6, the thin-film transistor 200 includes both the source electrode 207 and the drain electrode 208. However, one or more embodiments are not limited thereto. In an embodiment, for example, one pixel circuit for controlling an operation of one organic light-emitting diode may include a plurality of thin-film transistors. The active layer 203 included in a first thin-film transistor, which is one of these plurality of thin-film transistors, may be integrally formed as a single unitary indivisible body with the active layer 203 included in a second thin-film transistor, which is another one of the plurality of thin-film transistors. In such an embodiment, the first thin-film transistor may not have a drain electrode, and the second thin-film transistor may not have a source electrode. In an embodiment, for example, a drain region of the active layer 203 included in the first thin-film transistor and a source region of the active layer 203 included in the second thin-film transistor may be interconnected or integrally formed as a single unitary indivisible body.

In some embodiments, the source electrode 207 and/or the drain electrode 208 may be a portion of a signal line or a portion of a connection electrode. In an embodiment, for example, the source electrode 207 and/or the drain electrode 208 may be a portion of a data line, or a portion of a connection electrode which is located between the data line and the active layer 203 and electrically connects the data line to the active layer 203. In such an embodiment, the source electrode 207 and/or the drain electrode 208, which are a portion of a signal line or connection electrode, may be defined by a portion of a signal line or connection electrode which overlaps the active layer 203 when viewed from a direction perpendicular to the substrate 101 (i.e., in a plan view). The source electrode 207 and/or the drain electrode 208 may come into contact with the active layer 203 through contact holes defined in the interlayer insulating film 106.

A planarization layer 109 may cover the thin-film transistor 200. The planarization layer 109 may have an approximately flat surface despite the presence of the thin-film transistor 200 under the planarization layer 109. In such an embodiment, the planarization layer 109 may include an organic insulating material. In an embodiment, for example, the planarization layer 109 may include benzocyclobutene (BCB), hexamethyldisiloxane (HMDSO), polymethylmethacrylate (PMMA), polystyrene, polymer derivatives having a phenol-based group, acryl-based polymers, imide-based polymers such as polyimide, aryl ether-based polymers, amide-based polymers, fluorine-based polymers, p-xylene-based polymers, vinyl alcohol-based polymers, or a mixture thereof.

In some embodiments, at least one other insulating layer including an inorganic insulating material may be located between the thin-film transistor 200 and the planarization layer 109. In addition, a connection electrode or a signal line may be located between the insulating layer as described above and the planarization layer 109. In an embodiment where the insulating layers including the inorganic insulating material are located between the thin-film transistor 200 and the planarization layer 109, a connection electrode or a signal line may also be located between such insulating layers.

Organic light-emitting diodes 210, 220, and 230 may be disposed over the planarization layer 109. FIG. 6 shows a first organic light-emitting diode 210 which may emit light of a first color, a second organic light-emitting diode 220 which may emit light of a second color, and a third organic light-emitting diode 230 which may emit light of a third color. The first organic light-emitting diode 210 may include a first pixel electrode 211, a first intermediate layer 212 which includes an emission layer capable of emitting light of the first color, and a common electrode 213. The second organic light-emitting diode 220 may include a second pixel electrode 221, a second intermediate layer 222 which includes an emission layer capable of emitting light of the second color, and the common electrode 213. The third organic light-emitting diode 230 may include a third pixel electrode 231, a third intermediate layer 232 which includes an emission layer capable of emitting light of the third color, and the common electrode 213. In such an embodiment, the first pixel electrode 211 may be referred to as a first-color pixel electrode, the second pixel electrode 221 may be referred to as a second-color pixel electrode, and the third pixel electrode 231 may be referred to as a third-color pixel electrode.

The first pixel electrode 211, the second pixel electrode 221, the third pixel electrode 231 may be collectively referred to as pixel electrodes. Each of the pixel electrodes may have an isolated shape and may be spaced apart from each other. Each of the pixel electrodes may be a (semi-)light-transmitting electrode or a reflective electrode. In an embodiment, for example, each of the pixel electrodes may include a reflective layer which includes Ag, Mg, Al, Pt, Pd, Au, Ni, Nd, Ir, Cr, and a compound thereof, and a transparent conductive layer disposed over the reflective layer. The transparent conductive layer may include at least one selected from indium tin oxide (ITO), indium zinc oxide (IZO), zinc oxide (ZnO or ZnO₂), indium oxide (In₂O₃), indium gallium oxide (IGO), and aluminum zinc oxide (AZO). In an embodiment, for example, each of the pixel electrodes may have a three-layer structure of ITO/Ag/ITO.

A pixel-defining layer 119 may be disposed on the planarization layer 109. The pixel-defining layer 119 may define therein openings through which central portions of the pixel electrodes are respectively exposed. In an embodiment, the pixel-defining layer 119 may increase a distance between an edge of each of the pixel electrodes and the common electrode 213 thereon, thereby effectively preventing an arc or the like from occurring at the edge of each of the pixel electrodes. The pixel-defining layer 119 may include at least one organic insulating material selected from polyimide, polyamide, acrylic resin, BCB, and phenolic resin, and may be formed by spin coating or the like and then patterned by a photoresist or the like, so that openings may be defined in the pixel-defining layer 119.

At least a portion of the first intermediate layer 212 may be located in a first opening above the first pixel electrode 211 formed by the pixel-defining layer 119. The first opening may define an emission area of the first organic light-emitting diode 210. Similarly, at least a portion of the second intermediate layer 222 may be located in a second opening above the second pixel electrode 221 formed by the pixel-defining layer 119, and at least a portion of the third intermediate layer 232 may be located in a third opening above the third pixel electrode 231 formed by the pixel-defining layer 119. The second opening may define an emission area of the second organic light-emitting diode 220, and the third opening may define an emission area of the third organic light-emitting diode 230.

The first intermediate layer 212 may include an emission layer which may emit light of a first color, the second intermediate layer 222 may include an emission layer which may emit light of a second color, and the third intermediate layer 232 may include an emission layer which may emit light of a third color. The light of the first color may be red light, the light of the second color may be green light, and the light of the third color may be blue light.

The emission layers as described above may include an organic material which includes a fluorescent material or a phosphorous material. The emission layers may include a low-molecular weight organic material or a polymer organic material. Each of the first intermediate layer 212, the second intermediate layer 222, and the third intermediate layer 232 may include a hole transport layer (HTL) and/or a hole injection layer (HIL) which are located under the emission layer, and an electron transport layer (ETL) and/or an electron injection layer (EIL) which are located above the emission layer. Each of the emission layers may be patterned to have an isolated shape and may be disposed on a corresponding one of the pixel electrodes 211, 221, and 231. Layers other than the emission layers included in the first intermediate layer 212, the second intermediate layer 222, and the third intermediate layer 232 may be modified in various ways, such as being integrally formed as a single unitary indivisible body throughout a plurality of pixel electrodes.

The common electrode 213 may be a (semi-)light-transmitting electrode or a reflective electrode. In an embodiment, for example, the common electrode 213 may be a transparent or translucent electrode, and in such an embodiment, the common electrode 213 may include a metal thin-film which includes Li, Ca, lithium fluoride (LiF), Al, Ag, Mg, and a compound thereof. In some embodiments, the common electrode 213 may further include a transparent conductive oxide (TCO) film, such as an ITO film, an IZO film, a ZnO film, or an In₂O₃ film, disposed over the metal thin-film. The common electrode 213 may be integrally formed as a single unitary indivisible body throughout the entire surface of the display area DA and disposed above the pixel-defining layer 119 together with the first intermediate layer 212, the second intermediate layer 222, and the third intermediate layer 232. In an embodiment, for example, the common electrode 213 may be integrally formed as a single unitary indivisible body throughout the plurality of organic light-emitting diodes 210, 220, and 230.

Each of the first organic light-emitting diode 210, the second organic light-emitting diode 220, and the third organic light-emitting diode 230 may be electrically connected to a corresponding thin-film transistor 200. FIG. 6 shows an embodiment where the first pixel electrode 211 is in contact with the drain electrode 208 of the thin-film transistor 200, as an example. However, one or more embodiments are not limited thereto. Various modifications may be made, such as a connection electrode between the first pixel electrode 211 and the drain electrode 208 of the thin-film transistor 200. This also applies to the second pixel electrode 221 and the third pixel electrode 231.

A common voltage supply line 202 may be located in the peripheral area PA outside the display area DA. The common voltage supply line 202 may be electrically connected to the common electrode 213 and may apply a common voltage (e.g., ELVSS) to the common electrode 213. FIG. 6 shows an embodiment where the common voltage supply line 202 is disposed over the interlayer insulating film 106, similar to the source electrode 207 and/or the drain electrode 208 of the thin-film transistor 200. In such an embodiment, the common voltage supply line 202 may be simultaneously formed with the source electrode 207 and/or the drain electrode 208 of the thin-film transistor 200, and may include a same material. However, one or more embodiments are not limited thereto. In an embodiment, for example, similar to the gate electrode 205 of the thin-film transistor 200, the common voltage supply line 202 may be disposed over the gate insulating film 104. In such an embodiment, the common voltage supply line 202 may be simultaneously formed with the gate electrode 205 of the thin-film transistor 200, and may include a same material. Hereinafter, for convenience of description, an embodiment where the common voltage supply line 202 is disposed over the interlayer insulating film 106, similar to the source electrode 207 and/or the drain electrode 208 of the thin-film transistor 200 will be mainly described.

Because the common voltage supply line 202 may be electrically connected to the common electrode 213, as described above, a protective conductive layer 116 may be located between the common voltage supply line 202 and the common electrode 213. In an embodiment, for example, the protective conductive layer 116 may be in contact with the common voltage supply line 202, and the common electrode 213 may be in contact with the protective conductive layer 116 by extending to the peripheral area PA within the display area DA, such that the common electrode 213 may be electrically connected to the common voltage supply line 202.

In an embodiment, as shown in FIG. 6, the protective conductive layer 116 may be disposed over the planarization layer 109, similar to the first pixel electrode 211, the second pixel electrode 221, and the third pixel electrode 231. In this case, the protective conductive layer 116 may be simultaneously formed with the first pixel electrode 211, the second pixel electrode 221, and the third pixel electrode 231, and may include a same material. Thus, the protective conductive layer 116, the first pixel electrode 211, the second pixel electrode 221, and the third pixel electrode 231 may have a same layered structure.

In a manufacturing process for a display device, a process of forming various elements may be performed, from after the common voltage supply line 202 is formed until before the common electrode 213 is formed. When the protective conductive layer 116 does not exist, a problem may occur in which an upper surface of the common voltage supply line 202 is damaged or oxidized in the process described above. When a problem occurs, such as damage or oxidation of the upper surface of the common voltage supply line 202, an appropriate common voltage may not be applied to the common electrode 213 through the common voltage supply line 202. Thus, the protective conductive layer 116 may be disposed on the common voltage supply line 202, e.g., the protective conductive layer 116 may come into contact with the upper surface of the common voltage supply line 202, such that damage or oxidation of the upper surface of the common voltage supply line 202 may be effectively prevented or minimized.

In an embodiment, as described above, the first pixel electrode 211, the second pixel electrode 221, and the third pixel electrode 231 may include a transparent conductive layer which includes a conductive oxide, such as ITO, IZO, ZnO or ZnO₂, In₂O₃, IGO, or AZO. Accordingly, the protective conductive layer 116 may also include a transparent conductive layer which includes such a conductive oxide. Therefore, the upper surface of the protective conductive layer 116 as described above may be such that problems, such as oxidation, do not occur during a process after the protective conductive layer 116 is formed, or even when the problems do occur, severity of the problems may be minimized.

In FIG. 6, which is a cross-sectional view, a portion of the planarization layer 109 which covers a portion of the common voltage supply line 202 in a direction (-y direction) toward the display area DA is shown as being spaced apart from a portion of the planarization layer 109 which covers a portion of the common voltage supply line 202 in a direction (+y direction) toward an edge of the substrate 101. However, in some embodiments, the portion of the planarization layer 109 which covers the portion of the common voltage supply line 202 in the direction (-y direction) toward the display area DA may be integrally formed as a single unitary indivisible body with the portion of the planarization layer 109 which covers the portion of the common voltage supply line 202 in the direction (+y direction) toward the edge of the substrate 101. In an embodiment, for example, in a plan view, an opening defined in the planarization layer 109 through which at least a portion of the upper surface of the common voltage supply line 202 is exposed may surround most of the display area DA, but may not completely circle the display area DA. In some embodiments, the planarization layer 109 may define therein a plurality of openings which are spaced apart from each other and expose a portion of the upper surface of the common voltage supply line 202.

In an embodiment, as shown in FIG. 6, the pixel-defining layer 119 may cover the protective conductive layer 116, and may define therein an opening through which a portion of the upper surface of the protective conductive layer 116 is exposed. The common electrode 213 may come into contact with the upper surface of the protective conductive layer 116 through such an opening defined in the pixel-defining layer 119.

In FIG. 6, which is a cross-sectional view, a portion of the pixel-defining layer 119 which covers a portion of the protective conductive layer 116 in a direction (-y direction) toward the display area DA is shown as being spaced apart from a portion of the pixel-defining layer 119 which covers a portion of the protective conductive layer 116 in a direction (+y direction) toward an edge of the substrate 101. However, in some embodiments, the portion of the pixel-defining layer 119 which covers the portion of the protective conductive layer 116 in the direction (-y direction) toward the display area DA may be integrally formed as a single unitary indivisible body with the portion of the pixel-defining layer 119 which covers the portion of the protective conductive layer 116 in the direction (+y direction) toward the edge of the substrate 101. In an embodiment, for example, in a plan view, an opening defined in the pixel-defining layer 119 through which at least a portion of the upper surface of the protective conductive layer 116 is exposed may surround most of the display area DA, but may not completely circle the display area DA. In some embodiments, the pixel-defining layer 119 may define therein a plurality of openings which are spaced apart from each other and expose a portion of the upper surface of the protective conductive layer 116.

An encapsulation layer 300 may be disposed over the common electrode 213 to cover the pixel-defining layer 119, the first organic light-emitting diode 210, the second organic light-emitting diode 220, and the third organic light-emitting diode 230. The encapsulation layer 300 may include a first inorganic encapsulation layer 310, a bank layer 320, a second inorganic encapsulation layer 330, and polymer lenses 321, 322, and 323 which are organic encapsulation layers located between the first inorganic encapsulation layer 310 and the second inorganic encapsulation layer 330.

The first inorganic encapsulation layer 310 and the second inorganic encapsulation layer 330 may include at least one inorganic insulating material, such as silicon oxide (SiO₂), silicon nitride (SiNₓ), silicon oxynitride (SiOₓN_{y}), Al₂O₃, titanium oxide (TiO₂), tantalum oxide (Ta₂O₅), hafnium oxide (HfO₂), or ZnO₂, and may be formed by chemical vapor deposition or the like. The polymer lenses 321, 322, and 323, which are organic encapsulation layers, may include silicon-based resin, acryl-based resin (e.g., poly(methyl methacrylate) (PMMA), polyacrylic acid, or the like), epoxy-based resin, polyimide, or polyethylene.

Each of the first inorganic encapsulation layer 310 and the second inorganic encapsulation layer 330 may be integrally formed as a single unitary indivisible body to cover the display area DA. Each of the polymer lenses 321, 322, and 323, which are organic encapsulation layers, may be disposed over a corresponding one of the pixel electrodes. In an embodiment, the bank layer 320 may be disposed over the first inorganic encapsulation layer 310 to define opening portions corresponding to openings defined in the pixel-defining layer 119, respectively, to limit locations of such polymer lenses 321, 322, and 323. The polymer lenses 321, 322, and 323 may be located in these opening portions defined in the bank layer 320, respectively.

In an embodiment, as shown in FIG. 6, an area (i.e., a planar area when viewed in the third direction (z-axis direction) 320A1 of each of the opening portions defined in the bank layer 320 at the upper surface of the bank layer 320 may be greater than an area (i.e., a planar area when viewed in the third direction (z-axis direction) 119A2 of a corresponding one of the openings defined in the pixel-defining layer 119 at the lower surface of the pixel-defining layer 119. In addition, in each of the opening portions defined in the bank layer 320, the area 320A1 at the upper surface of the bank layer 320 may be greater than an area (i.e., a planar area when viewed in the third direction (z-axis direction) 320A2 at the lower surface of the bank layer 320. In some embodiments, even in the opening defined in the pixel-defining layer 119, an area 119A1 at the upper surface of the pixel-defining layer 119 may be greater than the area 119A2 at the lower surface of the pixel-defining layer 119.

The bank layer 320 includes or is formed of an organic insulating material, such as acryl-based resin, siloxane-based resin, epoxy-based resin, or fluorine-based resin, and may be formed by spin coating or the like and then patterned by a photoresist or the like, to form opening portions. In an embodiment, for example, the bank layer 320 may include a material in which porous silica is dispersed in a polymer matrix, a porous polymer, or a polymer material in which at least one hydrogen contained in hydrocarbon is substituted for fluorine. In an embodiment, for example, the bank layer 320 may include a poly(fluoroalkyl-co-methylsilsesquioxane) polymer. In some embodiments, if desired, the bank layer 320 may contain inorganic nanoparticles which are dispersed in such an organic insulating material. The inorganic nanoparticles may contain hollow silica, alumina, zeolite, or metal fluorides. Examples of the metal fluorides may include LiF or magnesium fluoride (MgF₂). Such a material for forming the bank layer 320 may be hydrophobic. In some embodiments, in a plan view or when viewed in the third direction (z-axis direction), opening portions spaced apart from each other may be defined in the bank layer 320, and each of the opening portions may have an isolated shape.

In a manufacturing process, the first inorganic encapsulation layer 310 may be formed on the common electrode 213 by chemical vapor deposition or the like, and then the bank layer 320 with opening portions defined therein may be formed. Next, a monomer for forming the polymer lenses 321, 322, and 323 may be located in the opening portions defined in the bank layer 320 by using inkjet printing, and then the monomer is cured by radiating ultraviolet rays or the like thereto, to form the polymer lenses 321, 322, and 323 which are organic encapsulation layers. Next, the second inorganic encapsulation layer 330 may be formed by chemical vapor deposition or the like to cover the bank layer 320 and the polymer lenses 321, 322, and 323, thereby forming the encapsulation layer 300.

In the display panel 10 and the electronic apparatus 1 including the display panel 10, according to an embodiment, the bank layer 320 with opening portions defined therein is provided, and a monomer may be provided in the opening portions of the bank layer 320 by inkjet printing. Thus, in such an embodiment, the bank layer 320 included in the encapsulation layer 300 is formed as described above, such that a dam that may be provided around an edge of the substrate 101 near the edge of the substrate 101 to prevent the monomer from overflowing to the outside of the substrate 101 may be omitted. As a result, an area or size of the peripheral area PA of the display panel 10 and the electronic apparatus 1 including the display panel 10 may be substantially or drastically reduced.

In an embodiment, each of the polymer lenses 321, 322, and 323 may be a convex lens having a convex upper surface toward the front (+z direction). Accordingly, the luminance in the front (+z direction) of the display panel 10 and the electronic apparatus 1 including the display panel 10 may be increased.

In an embodiment, as described above, a material for forming the bank layer 320 may be hydrophobic. In such an embodiment where the bank layer 320 is formed with such a hydrophobic material, the hydrophobic (liquid-repellent) material may be phase-separated during the formation process for the bank layer 320 and may exist mainly on the upper surface of the bank layer 320. Accordingly, when opening portions are formed through patterning, the upper surface of the bank layer 320 may become more hydrophobic than the inner surfaces of the opening portions, and the inner surfaces of the opening portions themselves may become relatively high in wettability or hydrophilic. Accordingly, in a state in which a monomer, which is a material for forming the polymer lenses 321, 322, and 323, is dotted into the opening portions defined in the bank layer 320 by an inkjet printing method, the monomer may be dotted in a convex lens shape when the dotting amount is sufficient. In this state, when the monomer is cured, each of the polymer lenses 321, 322, and 323 may become a convex lens with the upper surface convex in a forward direction (+z direction), as shown in FIG. 6.

In some embodiments, a black matrix BM may be disposed over/on the second inorganic encapsulation layer 330 and over the bank layer 320. The black matrix BM may be located outside of each of the opening portions defined in the bank layer 320, that is, the black matrix BM may not overlap each of the opening portions defined in the bank layer 320 in a plan view or when viewed in the third direction (z-axis direction). In some embodiments, the black matrix BM may be located outside of each of the openings defined in the pixel-defining layer 119, that is, the black matrix BM may not overlap each of the openings defined in the pixel-defining layer 119 in a plan view. In an embodiment, for example, in a plan view, the black matrix BM may have a shape surrounding each of the opening portions defined in the bank layer 320. As a result, in a plan view, the black matrix BM may have a mesh shape. In such an embodiment, the black matrix BM may define through-holes corresponding to the first pixel electrode 211, the second pixel electrode 221, and the third pixel electrode 231, respectively. Although not shown in FIG. 6, a color filter may be located in these through-holes defined in the black matrix BM. In an embodiment, for example, a first color filter capable of transmitting light of a first color may be located in a through-hole defined in the black matrix BM corresponding to the first pixel electrode 211, a second color filter capable of transmitting light of a second color may be located in a through-hole defined in the black matrix BM corresponding to the second pixel electrode 221, and a third color filter capable of transmitting light of a third color may be located in a through-hole defined in the black matrix BM corresponding to the third pixel electrode 231.

When an emission layer included in the first intermediate layer 212 emits light from a surface thereof, the light of the first color emitted from this emission layer travels in all directions. In some embodiments, light traveling toward the first pixel electrode 211 may be reflected by the first pixel electrode 211 and may travel in all directions (approximately in the +z direction). However, there is also light which travels in an oblique direction between the +z direction and the +y direction, and some of this light may travel to the black matrix BM and may not be emitted to the outside. Such a problem may occur in an emission layer included in the second intermediate layer 222 or an emission layer included in the third intermediate layer 232.

In the display panel 10 and the electronic apparatus 1 including the display panel 10, according to an embodiment, a refractive index of the polymer lenses 321, 322, and 323 may be greater than a refractive index of the bank layer 320. Accordingly, in such an embodiment, at least some of light which is emitted from the first intermediate layer 212, the second intermediate layer 222, and/or the third intermediate layer 232, passes through the polymer lenses 321, 322, and 323, and travels toward the black matrix BM may be totally reflected at the interface between the polymer lenses 321, 322, and 323 and the bank layer 320. As a result, the light reflected in this way no longer travels toward the black matrix BM but may pass through the interface between the polymer lenses 321, 322, and 323 and the second inorganic encapsulation layer 330 and travel to the outside of the display panel 10 and the electronic apparatus 1 including the display panel 10. As a result, the visibility of images or moving images displayed in the display area DA may be improved.

The bank layer 320, which has a refractive index lower than that of the polymer lenses 321, 322, and 323, may include an organic insulating material, such as acryl-based resin, siloxane-based resin, epoxy-based resin, or fluorine-based resin, as described above. In an embodiment, for example, the bank layer 320 may include a material in which porous silica is dispersed in a polymer matrix, a porous polymer, or a polymer material in which at least one hydrogen contained in hydrocarbon is substituted for fluorine. In an embodiment, for example, the bank layer 320 may include a poly(fluoroalkyl-co-methylsilsesquioxane) polymer. In addition, as described above, if desired, the bank layer 320 may contain inorganic nanoparticles which are dispersed in such an organic insulating material. The inorganic nanoparticles may contain hollow silica, alumina, zeolite, or metal fluorides. Examples of the metal fluorides may include LiF or MgF₂. The bank layer 320 including such a material may have a refractive index of about 1.4 or less.

The polymer lenses 321, 322, and 323, which has a relatively high refractive index compared to the bank layer 320, may include polyimide-based resin or polyarylene sulfide-based resin. In addition, if desired, the polymer lenses 321, 322, and 323 may include inorganic nanoparticles dispersed in such resin. The inorganic nanoparticles may include TiO₂, zinc sulfide (ZnS), zirconium dioxide (ZrO₂), or the like. The polymer lenses 321, 322, and 323 as described above may have a refractive index of about 1.7 or greater.

In some embodiments, the refractive index of the second inorganic encapsulation layer 330 may be greater than the refractive index of the polymer lenses 321, 322, and 323. Accordingly, in such embodiments, light passing through the polymer lenses 321, 322, and 323 and incident on the second inorganic encapsulation layer 330 may be effectively prevented from being totally reflected at the interface between the polymer lenses 321, 322, and 323 and the second inorganic encapsulation layer 330, or a degree of total reflection may be minimized. As a result, the luminance in the front (+z direction) of the display panel 10 and the electronic apparatus 1 including the display panel 10 may be increased. In an embodiment, the refractive index of the second inorganic encapsulation layer 330 may be about 1.9 or greater. In an embodiment where the second inorganic encapsulation layer 330 includes silicon oxide, the refractive index of the second inorganic encapsulation layer 330 may be controlled by adjusting an oxide content. In some embodiments, as described above, the bank layer 320 may have a refractive index of about 1.4 or less. In addition, the refractive index of the polymer lenses 321, 322, and 323 may be about 1.7 to less than about 1.9, and the refractive index of the second inorganic encapsulation layer 330 may be about 1.9 or greater.

In some embodiments, the refractive index of the polymer lenses 321, 322, and 323 themselves may be controlled. In an embodiment, for example, in the display panel 10 and the electronic apparatus 1 including the display panel 10, when a displayed image is bluish (depending on a viewing angle), a refractive index of one of the polymer lenses 321, 322, and 323 corresponding to the first pixel electrode 211 may be greater than refractive indices of the polymer lenses 321, 322, and 323 respectively corresponding to the second pixel electrode 221 and the third pixel electrode 231. Light emitted from the first intermediate layer 212 which is on the first pixel electrode 211 may be red light, and by allowing more total reflection to occur at the interface between the bank layer 320 and the polymer lens 321 corresponding to the first pixel electrode 211 among the polymer lenses 321, 322, and 323, more red light may travel forward (in the +z direction), thereby allowing color coordinates of the image displayed on the display panel 10 and the electronic apparatus 1 including the display panel 10 to become preset color coordinates.

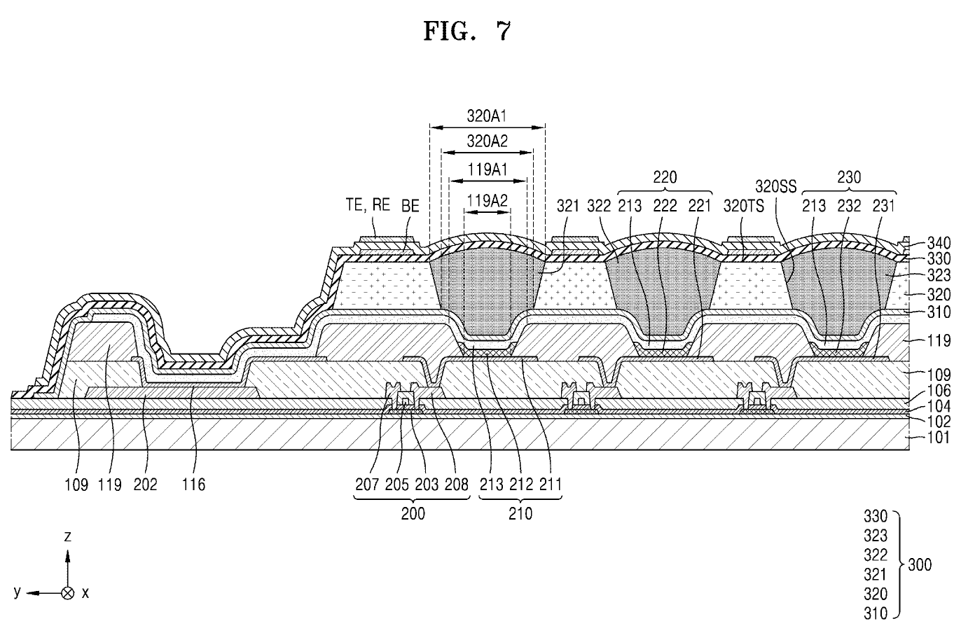

FIG. 7 is a cross-sectional view schematically illustrating the display panel 10 according to an embodiment. In an embodiment, as shown in FIG. 7, the display panel 10 and the electronic apparatus 1 including the display panel 10 may further include a touchscreen electrode on the bank layer 320. FIG. 7 shows an embodiment where a bridge electrode BE is disposed over/on the second inorganic encapsulation layer 330 to be located over the bank layer 320, and a driving electrode TE or a detection electrode RE is disposed over a touch insulating layer 340 which covers the bridge electrode BE. The display panel 10 and the electronic apparatus 1 including the display panel 10 may have a touchscreen function using a mutual capacitance method in which voltages charged in mutual capacitances are detected through the detection electrodes RE after a driving signal is applied to the driving electrodes TE. Elements other than the touchscreen electrode are substantially the same as those described above with reference to FIG. 6, and any repetitive detailed description thereof will be omitted or simplified.

In an embodiment, the detection electrodes RE may be arranged, for example, in the first direction (x-axis direction) and electrically connected to each other. The driving electrodes TE may be arranged, for example, in the second direction (y-axis direction) which crosses the first direction (x-axis direction), and electrically connected to each other. The driving electrodes TE and the detection electrodes RE may be located in a same layer as each other, but electrically separated from each other. In order for the detection electrodes RE and the driving electrodes TE to be electrically separated in areas where the detection electrodes RE and the driving electrodes TE cross or overlap each other, the driving electrodes TE adjacent to each other in the second direction (y-axis direction) may be connected to each other through the bridge electrode BE, and the detection electrodes RE adjacent to each other in the first direction (x-axis direction) may be connected to each other through another bridge electrode BE.

The touchscreen electrode, such as the driving electrode TE or the detection electrode RE, or the bridge electrode BE may be located outside (or not to overlap) each of the opening portions defined in the bank layer 320. In some embodiments, the touchscreen electrode, such as the driving electrode TE or the detection electrode RE, or the bridge electrode BE, may be located outside (or not to overlap) each of the openings defined in the pixel-defining layer 119. In an embodiment, for example, in a plan view, the driving electrode TE may have a shape surrounding each of some opening portions defined in the bank layer 320. The detection electrode RE may also have a shape surrounding each of some other opening portions defined in the bank layer 320.

In the display panel 10 and the electronic apparatus 1 including the display panel 10, according to an embodiment, the refractive index of the polymer lenses 321, 322, and 323 may be greater than the refractive index of the bank layer 320. Accordingly, in such an embodiment, at least some of light which is emitted from the first intermediate layer 212, the second intermediate layer 222, and/or the third intermediate layer 232, passes through the polymer lenses 321, 322, and 323, and travels toward the touchscreen electrode, such as the driving electrode TE, the detection electrode RE, or the bridge electrode BE may be totally reflected at the interface between the polymer lenses 321, 322, and 323 and the bank layer 320. As a result, the light reflected in this way no longer travels towards the touchscreen electrode but may pass through the interface between the polymer lenses 321, 322, and 323 and the second inorganic encapsulation layer 330 and travel to the outside of the display panel 10 and the electronic apparatus 1 including the display panel 10. As a result, the visibility of images or moving images displayed in the display area DA may be improved.

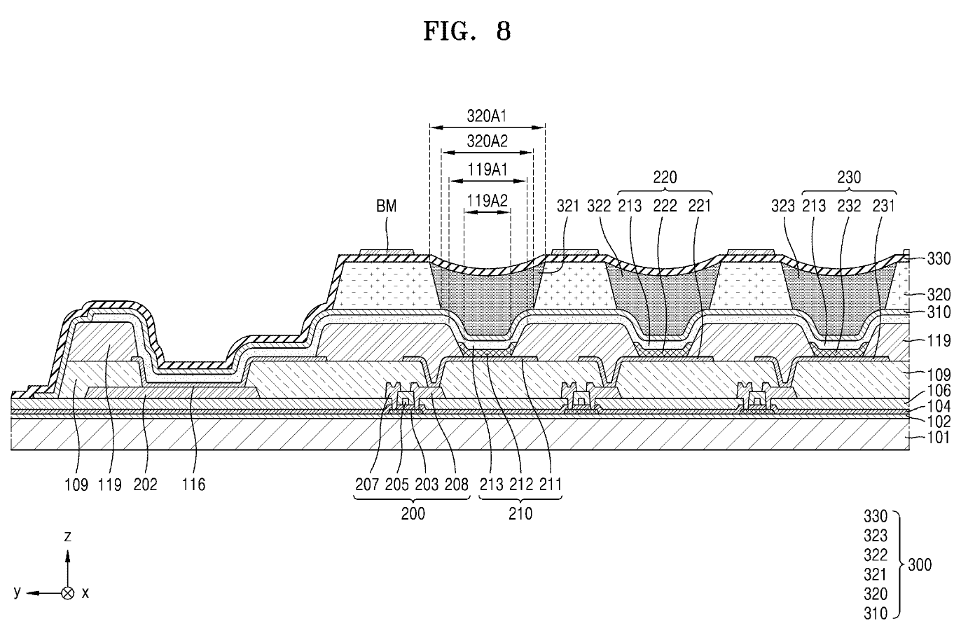

FIG. 8 is a cross-sectional view schematically illustrating a display panel 10 according to an embodiment. As shown in FIG. 8, in an embodiment, each of the polymer lenses 321, 322, and 323 may have a concave lens shape with a concave upper surface. In such an embodiment, as described above, a material for forming the bank layer 320 may be hydrophobic. In such an embodiment where the bank layer 320 is formed with such a hydrophobic material, the hydrophobic (liquid-repellent) material may be phase-separated during the formation process for the bank layer 320 and may exist mainly on the upper surface of the bank layer 320. Accordingly, when opening portions are formed through patterning, the upper surface of the bank layer 320 may become more hydrophobic than the inner surfaces of the opening portions, and the inner surfaces of the opening portions themselves may become relatively high in wettability or hydrophilic. Accordingly, in a state in which a monomer, which is a material for forming the polymer lenses 321, 322, and 323, is dotted into the opening portions defined in the bank layer 320 by an inkjet printing method, the monomer may be dotted in a concave lens shape when the dotting amount is insufficient. In this state, when the monomer is cured, each of the polymer lenses 321, 322, and 323 may become a concave lens with a concave upper surface, as shown in FIG. 8.

Although a structure of an embodiment of the display panel 10 is mainly described above, one or more embodiments are not limited thereto. The electronic apparatus 1 including the display panel 10 may be considered to fall within the scope of an embodiment.

According to an embodiment, as described above, a display panel on which high-quality images may be displayed, and an electronic apparatus including the display panel may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a substrate;
a plurality of pixel electrodes disposed on the substrate, wherein each of the plurality of pixel electrodes has an isolated shape;
a pixel-defining layer which covers an edge of each of the plurality of pixel electrodes, wherein openings, through which central portions of the plurality of pixel electrodes are exposed, are defined in the pixel-defining layer;
a common electrode disposed above the pixel-defining layer and the plurality of pixel electrodes, and integrally formed as a single unitary indivisible body;
a first inorganic encapsulation layer disposed on the common electrode;
a bank layer disposed on the first inorganic encapsulation layer, wherein opening portions corresponding to the openings, respectively, are defined in the bank layer;
polymer lenses arranged in the opening portions, wherein each of the polymer lenses has a refractive index higher than a refractive index of the bank layer, and an upper surface of each of the polymer lenses has a lens shape; and
a second inorganic encapsulation layer which covers the bank layer and the polymer lenses.

2. The display panel of claim 1, wherein an area of each of the opening portions in an upper surface of the bank layer is greater than an area of a corresponding one of the openings in a lower surface of the pixel-defining layer.

3. The display panel of claim 1, wherein each of the opening portions has a greater area at an upper surface of the bank layer than at a lower surface of the bank layer.

4. The display panel of claim 1, wherein a refractive index of the second inorganic encapsulation layer is greater than a refractive index of the polymer lenses.

5. The display panel of claim 1, further comprising a black matrix disposed on the second inorganic encapsulation layer and over the bank layer.

6. The display panel of claim 5, wherein, when viewed from a direction perpendicular to the substrate, the black matrix is located outside the opening portions and the openings.

7. The display panel of claim 1, further comprising a touchscreen electrode disposed on the second inorganic encapsulation layer and over the bank layer.

8. The display panel of claim 7, wherein, when viewed from a direction perpendicular to the substrate, the touchscreen electrode is located outside the opening portions and the openings.

9. The display panel of claim 1, wherein the plurality of pixel electrodes comprise a first-color pixel electrode, a second-color pixel electrode, and a third-color pixel electrode, and
a refractive index of one of the polymer lenses corresponding to the first-color pixel electrode is greater than refractive indices of the polymer lenses corresponding to the second-color pixel electrode and the third-color pixel electrode.

10. The display panel of claim 1, wherein the lens shape comprises a convex lens shape.

11. The display panel of claim 1, wherein an upper surface of the bank layer is hydrophobic, and inner surfaces of the bank layer defining the opening portions are hydrophilic.

12. An electronic apparatus comprising:
a display panel; and
a lower cover which constitutes an exterior of the electronic apparatus, wherein an opening, through which a portion of the display panel is exposed, is defined in the lower cover,
wherein the display panel comprises:
a substrate;
a plurality of pixel electrodes disposed on the substrate, wherein each of the plurality of pixel electrodes has an isolated shape;
a pixel-defining layer which covers an edge of each of the plurality of pixel electrodes, wherein openings, through which central portions of the plurality of pixel electrodes are exposed, are defined in the pixel-defining layer;
a common electrode disposed above the pixel-defining layer and the plurality of pixel electrodes, and integrally formed as a single unitary indivisible body;
a first inorganic encapsulation layer disposed on the common electrode;
a bank layer disposed on the first inorganic encapsulation layer, wherein opening portions corresponding to the openings, respectively, are defined in the bank layer;
polymer lenses arranged in the opening portions, wherein each of the polymer lenses has a refractive index higher than a refractive index of the bank layer, and an upper surface of each of the polymer lenses has a lens shape; and
a second inorganic encapsulation layer which covers the bank layer and the polymer lenses.

13. The electronic apparatus of claim 12, wherein an area of each of the opening portions in an upper surface of the bank layer is greater than an area of a corresponding one of the openings in a lower surface of the pixel-defining layer.

14. The electronic apparatus of claim 12, wherein each of the opening portions has a greater area at an upper surface of the bank layer than at a lower surface of the bank layer.

15. The electronic apparatus of claim 12, wherein a refractive index of the second inorganic encapsulation layer is greater than a refractive index of the polymer lenses.

16. The electronic apparatus of claim 12, further comprising a black matrix disposed on the second inorganic encapsulation layer and over the bank layer,
wherein, when viewed from a direction perpendicular to the substrate, the black matrix is located outside the opening portions and the openings.

17. The electronic apparatus of claim 12, further comprising a touchscreen electrode disposed on the second inorganic encapsulation layer and over the bank layer,
wherein, when viewed from a direction perpendicular to the substrate, the touchscreen electrode is located outside the opening portions and the openings.

18. The electronic apparatus of claim 12, wherein the plurality of pixel electrodes comprise a first-color pixel electrode, a second-color pixel electrode, and a third-color pixel electrode, and
a refractive index of one of the polymer lenses corresponding to the first-color pixel electrode is greater than refractive indices of the polymer lenses corresponding to the second-color pixel electrode and the third-color pixel electrode.

19. The electronic apparatus of claim 12, wherein the lens shape comprises a convex lens shape.

20. The electronic apparatus of claim 12, wherein an upper surface of the bank layer is hydrophobic, and inner surfaces of the bank layer defining the opening portions are hydrophilic.
